(19) United States
(12) Patent Application Publication
(10) Pub. No.: US 2020/0027757 A1
(43) Pub. Date: Jan. 23, 2020

(54) Die Transfer Method and Die Transfer System Thereof

(71) Applicant: AeroTrans Technology Co., Ltd., Taipei City 110 (TW)

(72) Inventor: I-Chun Lin, Taipei City (TW)

(21) Appl. No.: 16/505,904

(22) Filed: Jul. 9, 2019

(30) Foreign Application Priority Data
Jul. 23, 2018 (TW) 107125365

(51) Int. Cl. H01L 21/677; H01L 21/68; H01L 23/00

(52) U.S. Cl. CPC H01L 21/677; H01L 2224/83894; H01L 24/83; H01L 21/68

(57) ABSTRACT

A die transfer method and a die transfer system thereof are disclosed. The die transfer method includes the following steps: providing a wafer to generate a plurality of dies; transferring a plurality of dies to a surface of a substrate to fix the plurality of dies on the surface of the substrate; aligning the substrate with a target substrate, wherein the target substrate has a landing site and the position of at least one die corresponds to the position of the landing site; in an air environment or a liquid environment, executing lyophilic or lyophobic treatment as compared to the periphery respectively to a bonding surface between the at least one die and the landing site of the target substrate; transferring the at least one die onto the landing site of the target substrate; and fixing the at least one die at the landing site.

### BACKGROUND OF THE INVENTION

### 1. Field of the Invention

The present invention relates to a die transfer method and a die transfer system thereof, particularly to a die transfer method with a die self-alignment function and a die transfer system thereof.

### 2. Description of the Related Art

With the advancement of technology, the electronic die has become widely used in various electronic devices. Nevertheless, several methods for arranging the electronic die on a substrate, such as Surface Mount Technology (SMT), Wafer-to-Wafer Transfer, Electrostatic Transfer, Elastomer Stamp, and Micro Transfer (μTP) technology, have been disclosed in the prior art.

The Surface Mount Technology (SMT) enables die to be individually packaged into a surface mount device (SMD) and then made into a tape. As such, the component stage is completed. The tape is loaded into a surface mounter, and each SMD is individually mounted on the circuit board using a vacuum nozzle. Then the SMDs are fixed onto the substrate by a reflow oven. In Wafer-to-Wafer Transfer, a native substrate of the die is bonded to a target substrate, and then the native substrate is peeled off to transfer the die to the target substrate. In Electrostatic Transfer, the die is electrostatically lifted, transferred, and placed on the target substrate. The Elastomer Stamp method uses a slightly viscous PDMS as the stamp to fine tune the speed and force of the pickup head, destroying the weak structure of the component to achieve the action of lifting it. After transfer to the target substrate, the stamp action is achieved by the adhesion difference between the two sides of the die, the fixing layer on the pickup head and the target substrate. However, the above methods must be very precise in positioning the die; otherwise, the die cannot be transferred to the target substrate.

Accordingly, it is necessary to devise a new die transfer method and a die transfer system thereof to solve the problem in the prior art.

### SUMMARY OF THE INVENTION

It is a primary objective of the present invention to provide a die transfer method with a die self-alignment effect.

It is another primary objective of the present invention to provide a die transfer system used for the aforementioned method.

To achieve the above objectives, the die transfer method of the present invention includes the following steps: providing a wafer to generate a plurality of dies; transferring a plurality of dies to a surface of a substrate to fix the plurality of dies on the surface of the substrate; aligning the substrate with a target substrate, wherein the target substrate has a landing site and the position of at least one die corresponds to the position of the landing site; in an air environment or a liquid environment, executing lyophilic or lyophobic treatment as compared to a periphery respectively to a bonding surface between the at least one die and the landing site of the target substrate; transferring the at least one die onto the landing site of the target substrate; and fixing the at least one die at the landing site.

The die transfer system of the present invention is suitable for transferring a plurality of dies. The die transfer system includes a substrate, a target substrate, and a transfer module. The substrate has a surface. After the plurality of dies is generated from the wafer, the dies are transferred to the surface and fixed thereon. The target substrate has a landing site. When the substrate is aligned with the target substrate, the position of at least one die corresponds to the position of the landing site. Further, in the air environment or the liquid environment, lyophilic treatment or lyophobic treatment as compared to a periphery is executed to the bonding surface between the at least one die and the landing site of the target substrate respectively. The transfer module is used to transfer the at least one die on the substrate to the landing site of the target substrate.

### BRIEF DESCRIPTION OF THE DRAWINGS

FIG. 1 is a schematic diagram illustrating the transfer of the die to the landing site in a first embodiment of the present invention;

FIG. 2 is a flowchart showing the steps of a die transfer method of the present invention;

FIG. 3 is a flowchart showing the steps in the method of transferring the die to a landing site in the first embodiment of the present invention;

FIGS. 4A-4C are schematic diagrams showing the sequence of transferring the die to the landing site in the first embodiment of the present invention;

FIG. 5 is a schematic diagram illustrating the transfer of the die to the landing site in a second embodiment of the present invention;

FIG. 6 is a flowchart showing steps in the method of transferring the die to a landing site in the second embodiment of the present invention;

FIGS. 7A-7C are schematic diagrams showing the sequence of transferring the die to the landing site in the second embodiment of the present invention; and

FIGS. 8A-8C are schematic diagrams showing the die and specific patterns of a bonding surface of the landing site of the present invention.

### DETAILED DESCRIPTION OF THE PREFERRED EMBODIMENT

Hereafter, the technical content of the present invention will be better understood with reference to preferred embodiments.

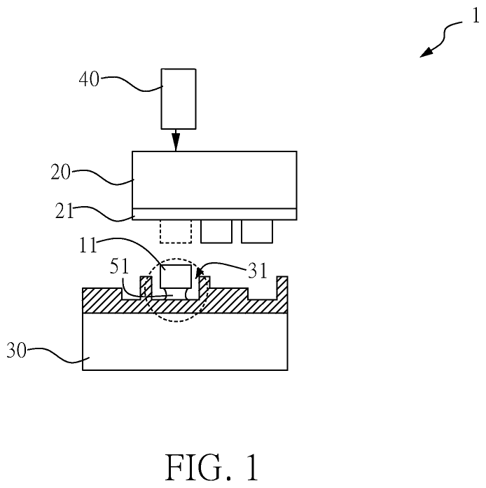

Hereafter please first refer to FIG. 1, which is a schematic diagram illustrating the transfer of a die to a landing site according to a first embodiment of the present invention.

A die transfer system 1 of the present invention is applicable to transferring a plurality of dies 11 that is generated from a wafer 10. Since the technique of generating the die 11 using the wafer 10 is familiar to those with ordinary skill in the art, the principle will not be described herein. The die transfer system 1 includes a substrate 20, a target substrate 30, and a transfer module 40. The substrate 20 has a surface 21. After the plurality of dies 11 is generated from the wafer 10, the plurality of dies 11 is transferred and fixed to the surface 21 by the Wafer-to-Wafer Transfer technology.

The target substrate 30 has a landing site 31. When the substrate 20 is aligned with the target substrate 30, at least one of the dies 11 on the surface 21 corresponds to the position of the landing site 31. The landing site 31 of the target substrate 30 is provided with a corresponding well or an adhesive layer to facilitate positioning of the die 11. The transfer module 40 may employ techniques such as Surface Mount Technology (SMT), Wafer-to-Wafer Transfer, Electrostatic Transfer, Elastomer Stamp or Micro Transfer (μTP), but the present invention is not limited to the way the die 11 is removed from the substrate 20. Accordingly, the transfer module 40 can drop a specific single or a plurality of dies 11 to transfer the die 11 to the landing site 31 of the target substrate 30, and finally fix the die 11 to the landing site 31. For example, when the electrode of die 11 faces up, it can be fixed by light (usually UV, but not limited thereto) or heat with insulating adhesive. When the electrode of die 11 faces down, that is, it is a flip chip, solder such as solder paste, Ball Grid Array (BGA) or Anisotropic Conductive Film (ACF) can be used, and then it is fixed onto the target substrate 30 by heat or light. Then the die 11 and the electrode of the target substrate 30 are connected, but the present invention is not limited to the way the die 11 is fixed. It should be noted that the distance between different landing sites 31 on the target substrate 30 is M times the distance between any two adjacent dies 11 on the substrate 20, where M is a positive integer, but the present invention does not limit the size of M.

The die transfer system 1 of the present invention has the die self-alignment function. Therefore, in a first embodiment of the present invention, lyophilic treatment as compared to a periphery can be executed to the bonding surface between the die 11 and the landing site 31 of the target substrate 30, such that the die 11 is placed above the landing site 31 of the target substrate 30 in an air environment. That is, a liquid film 51 is provided at the landing site 31. Accordingly, when the die 11 is dropped close to the landing site 31, the liquid film 51 will align the die 11 with the landing site by surface tension. Finally, the die 11 will be fixed with an adhesive at the landing site 31.

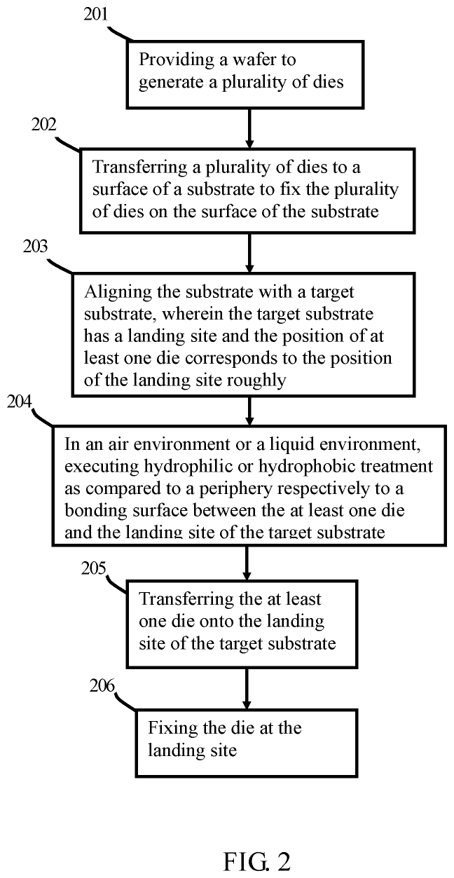

Please refer to FIG. 2, which is a flowchart showing the steps of the die transfer method of the present invention. It should be noted here that although the aforementioned die transfer system 1 is taken as an example to describe the die transfer method of the present invention, the die transfer method of the present invention is not limited to the use of a die transfer system 1 having the same structure described above.

Firstly, in Step 201: Providing a wafer to generate a plurality of dies.

First, a wafer is used to generate a plurality of dies 11.

Then, in Step 202: Transferring a plurality of dies to a surface of a substrate to fix the plurality of dies on the surface of the substrate.

The plurality of dies 11 is transferred and fixed to the surface 21 of the substrate 20 by the Wafer-to-Wafer Transfer technology.

Next, in Step 203: Aligning the substrate with a target substrate, wherein the target substrate has a landing site and the position of at least one die corresponds to the position of the landing site roughly.

The substrate 20 is aligned with the target substrate 30, such that the at least one die 11 on the surface 21 of the substrate 20 corresponds to the landing site 31 roughly.

Then, in Step 204: In an air environment or a liquid environment, executing lyophilic or lyophobic treatment as compared to a periphery respectively to a bonding surface between the at least one die and the landing site of the target substrate.

At this time, the die transfer system 1 can be in an air environment or a liquid environment. If the die transfer system 1 is in an air environment, it executes a lyophilic treatment as compared to a periphery to a bonding surface between the at least one die 11 and the landing site 31 of the target substrate 30. If the die transfer system 1 is in a liquid environment, it executes a lyophobic treatment as compared to the periphery to the bonding surface between the at least one die 11 and the landing site 31 of the target substrate 30. For example, if a lyophobic material is placed around the bonding surface, the bonding surface will form a lyophilic region compared to the periphery; conversely, if a lyophobic material is provided on the bonding surface, the bonding surface will become a lyophobic region compared to the periphery. Alternatively, if a lyophilic material is provided on the bonding surface, the bonding surface will become a lyophilic region compared to the periphery, if a lyophilic material is provided around the bonding surface, the bonding surface will form a lyophobic region compared to the periphery. Alternatively, a combination of a lyophilic material and a lyophobic material can be used, but the present invention is not limited to the above-mentioned application methods.

Next, in Step 205: Transferring the at least one die onto the landing site of the target substrate.

At this time, the transfer module 40 drops the die 11, thereby transferring the die 11 to the landing site 31 of the target substrate 30.

Finally, in Step 206: Fixing the die at the landing site.

The die 11 is fixed with an adhesive at the landing site 31, but the present invention is not limited to the adhesive material or the fixing method.

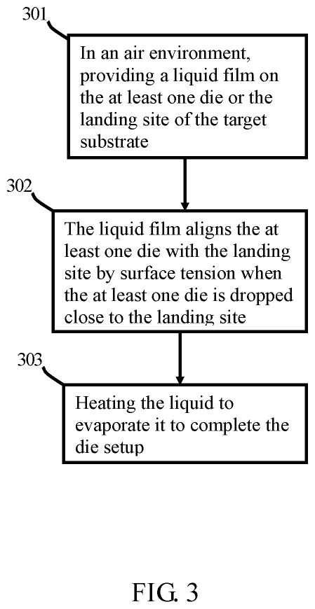

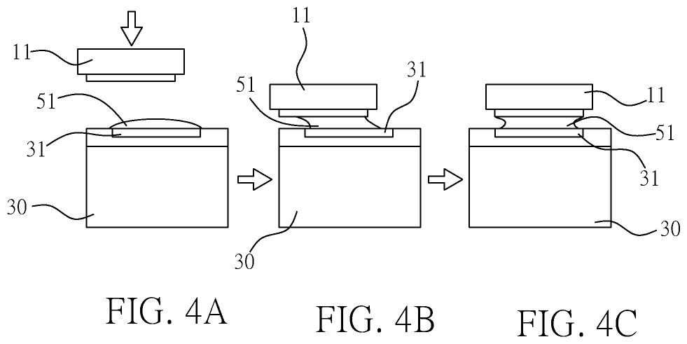

Please refer to FIG. 3, which is a flowchart showing the steps in the method of transferring the die to a landing site in the first embodiment of the present invention, and FIGS. 4A-4C, which are schematic diagrams showing the sequence of transferring the die to the landing site in the first embodiment of the present invention.

First, in Step 301: In an air environment, providing a liquid film on the at least one die or the landing site of the target substrate.

As shown in FIG. 4A, first, in an air environment, a liquid film 51 is provided on the bonding surface of the at least one die 11 or the landing site 31 of the target substrate 30. Furthermore, the liquid film 51 can also be provided respectively at the bonding surface of the at least one die 11 and the landing site 31 of the target substrate 30.

Then, in Step 302: The liquid film aligns the at least one die with the landing site by surface tension when the at least one die is dropped close to the landing site.

Then, as shown in FIG. 4B, when the die 11 is dropped close to the landing site 31, the liquid film 51 corrects the alignment of the die 11 with the landing site by surface tension. Therefore, as shown in FIG. 4C, the die 11 is placed on the landing site 31 of the target substrate 30.

Finally, in Step 303: Heating the liquid to evaporate it to complete the die setup.

After the target substrate 30 is slightly heated and the liquid film 51 is completely evaporated, the die 11 transfer alignment process can be completed. Finally, the die 11 is fixed with an adhesive at the landing site 31.

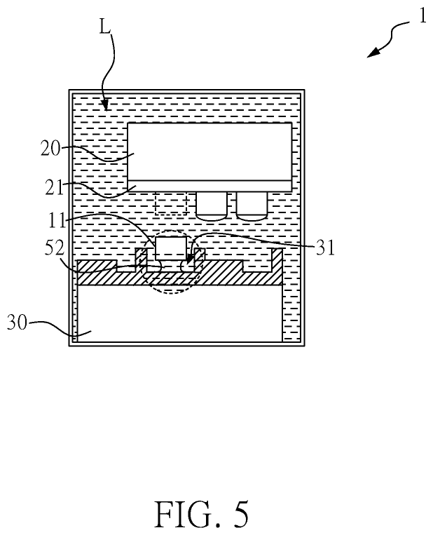

Please refer to FIG. 5, which is a schematic diagram illustrating the transfer of the die to the landing site in a second embodiment of the present invention.

In the second embodiment of the present invention, the lyophobic treatment as compared to the periphery is executed to the die 11 and a bonding surface between the landing site 31 of the target substrate 30, such that the die 11 is placed above the landing site 31 of the target substrate 30 in a liquid environment L. An air film 52 is formed respectively on the bonding surface between the die 11 and the landing site 31. Accordingly, when the die 11 is dropped close to the landing site 31, the air film 52 of the die 11 and the landing site 31 is superposed by a liquid pressure, such that the die 11 is aligned with the landing site 31. Finally, the die 11 is fixed with an adhesive at the landing site 31.

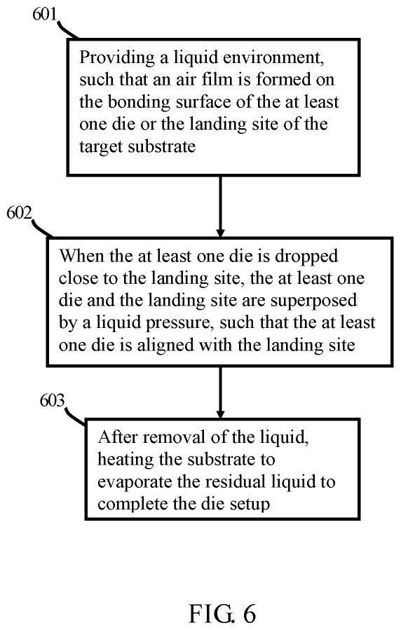

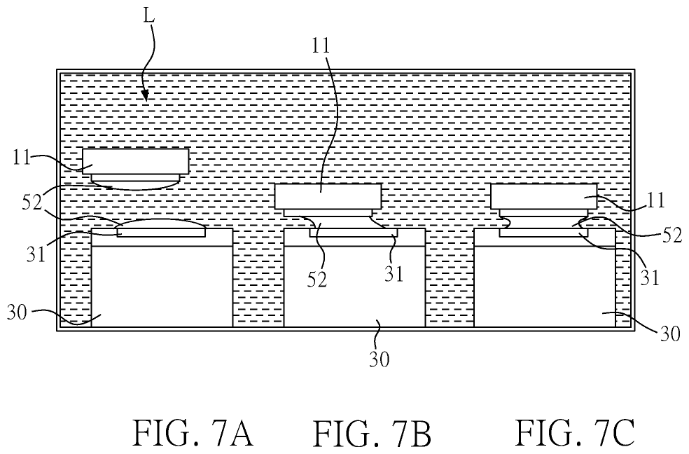

Please refer to both FIG. 6 for a flowchart showing the steps of a method for transferring a die to a landing site of the second embodiment of the present invention, and FIGS. 7A-7C for schematic diagrams showing the sequence of transferring a die to the landing site of the second embodiment of the present invention.

First, in Step 601: Providing a liquid environment, such that an air film is formed on the bonding surface of the at least one die or the landing site of the target substrate.

As shown in FIG. 7A, first, a liquid environment L is provided, such that an air film 52 is formed respectively at the bonding surface of the die 11 or the landing site 31 of the target substrate 30. Besides, the air film 52 can also be formed respectively at the bonding surface of the die 11 and the landing site 31 of the target substrate 30.

Then, in Step 602: When the at least one die is dropped close to the landing site, the at least one die and the landing site are superposed by a liquid pressure, such that the at least one die is aligned with the landing site.

Next, as shown in FIG. 7B, when the die 11 is dropped to approach the landing site 31, the two air films 52 between the die 11 and the landing site 31 are further superposed by a liquid pressure, such that the die 11 is corrected to be aligned with the landing site 31. Thus, as shown in FIG. 7C, the die 11 is placed on the landing site 31 of the target substrate 30.

Finally, in Step 603: After removal of the liquid, heating the substrate to evaporate the residual liquid to complete the die setup.

In the last step, the target substrate 30 is removed from the liquid and then heated slightly so that the residual liquid on the target substrate 30 will be completely evaporated, and then the transfer of the die 11 is completed. Finally, the die 11 is fixed with an adhesive at the landing site 31.

It can be seen from the above that in the first embodiment and the second embodiment, the die 11 has an automatic alignment function at the landing site 31. Therefore, the alignment accuracy between the substrate 20 and the target substrate 30 does not need to be extremely high.

It should be noted here that the die transfer method of the present invention is not limited to the order of the above steps, and that the order of the above steps may be changed as long as the objective of the present invention can be achieved.

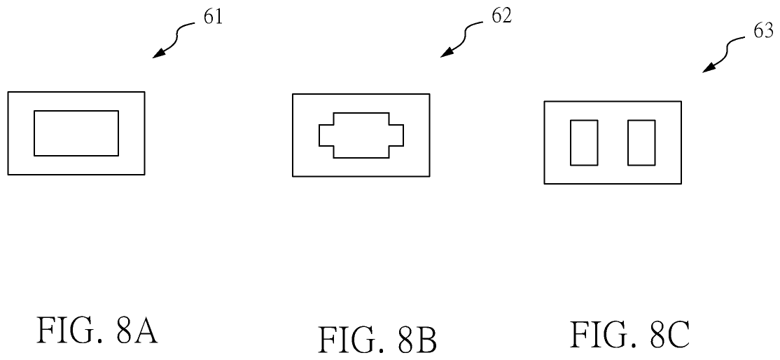

Please refer to FIGS. 8A-8C, which are schematic diagrams showing the die and specific patterns of a bonding surface of the landing site of the present invention.

The die 11 and the bonding surface of the landing site 31 can be patterned into specific patterns 61, 62 or 63 to accelerate the speed and accuracy of self-alignment. For example, the specific pattern 61 of FIG. 8A may be a rectangle, the specific pattern 62 of FIG. 8B may be a cross type, and the specific pattern 63 of FIG. 8C may be two small rectangles side by side, but the present invention is not limited to the patterns shown in FIGS. 8A-8C. However, it should be noted that as long as the specific pattern is a single block of a non-circular shape or an irregular polygon, or a plurality of blocks of any shape, the rotation error of the transposition caused by the rotation of the die 11 can be suppressed. For example, if the specific pattern is a rectangle, when the initial rotation error of the die is less than 90 degrees, the die can be corrected by self-alignment. In generally, the error of rotation should be controlled within 90 degrees, so as long as the pattern is the non-circular shape or the irregular polygon, the function of correcting the alignment error can be achieved.

Accordingly, with the automatic alignment function of the die transfer system 1 and the die transfer method of the present invention, the accuracy of setting the die 11 at the landing site 31 can be increased, the efficiency can be improved effectively, and the mechanism cost can be reduced.

It should be noted that the preferred embodiments of the present invention described above are merely illustrative. To avoid redundancy, not all the possible combinations of changes are documented in detail. However, it shall be understood by those skilled in the art that each of the modules or elements described above may not be necessary. For the implementation of the present invention, the present invention may also contain other detailed, conventional modules or elements, each module or component is likely to be omitted or modified depending on variable needs, and other modules or elements may not necessarily exist between two of any modules, all without departing from the scope of the invention as defined solely by the appended claims.

What is claimed is:

1. A die transfer method, comprising the following steps:
providing a wafer to generate a plurality of dies;
transferring a plurality of dies to a surface of a substrate to fix the plurality of dies on the surface of the substrate;
aligning the substrate with a target substrate, wherein the target substrate has a landing site, and the position of at least one die corresponds to the position of the landing site;
in an air environment or a liquid environment, executing lyophilic or lyophobic treatment as compared to a periphery respectively to a bonding surface between the at least one die and the landing site of the target substrate;
transferring the at least one die onto the landing site of the target substrate; and
fixing the at least one die at the landing site.

2. The die transfer method as claimed in claim 1, wherein the lyophilic treatment compared to the periphery further comprises the following steps:
in the air environment, providing a liquid film at the at least one die or the landing site;
the liquid film aligns the at least one die with the landing site by surface tension when the at least one die is dropped close to the landing site.

3. The die transfer method as claimed in claim 1, wherein the lyophobic treatment compared to the periphery further comprises the following steps:
providing the liquid environment, such that an air film is formed on the bonding surface of the at least one die or the landing site; and
when the at least one die is dropped close to the landing site, the air film of the at least one die or the landing site is superposed by a liquid pressure, such that the at least one die is aligned with the landing site.

4. The die transfer method as claimed claim 1, further comprising the following step:
performing pattern processing on the bonding surface of the at least one die and the landing site.

5. A die transfer system, applicable to transferring a plurality of dies generated from a wafer, the die transfer system comprising:
a substrate, having a surface, wherein after the plurality of dies is generated from the wafer, the dies are transferred to the surface to fix the dies;
a target substrate, having a landing site, wherein when the substrate is aligned with the target substrate, the position of at least one die corresponds to the position of the landing site, and in an air environment or a liquid environment, executing lyophilic or lyophobic treatment as compared to a periphery respectively to a bonding surface between the at least one die and the landing site of the target substrate; and
a transfer module, used to transfer the at least one die on the substrate to the landing site of the target substrate.

6. The die transfer system as claimed in claim 5, wherein in the air environment, the landing site is provided with a liquid film at the at least one die or the landing site such that when the at least one die is dropped close to the landing site, the liquid film aligns the at least one die with the landing site by surface tension.

7. The die transfer system as claimed in claim 5, wherein in a liquid environment, the at least one die or the landing site forms an air film, such that when the at least one die is dropped close to the landing site, the air film of the at least one die or the landing site is superposed by a liquid pressure, such that the at least one die is aligned with the landing site.

8. The die transfer system as claimed in claim 5, wherein the at least one die and the bonding site have a specific pattern.

9. The die transfer system as claimed in claim 8, wherein the specific pattern is a single block of a non-circular shape or an irregular polygon, or a plurality of blocks of any shape.
